(19) United States
(12) Patent Application Publication
(10) Pub. No.: US 2005/0093594 A1
(43) Pub. Date: May 5, 2005

(54) DELAY LOCKED LOOP PHASE BLENDER CIRCUIT

(75) Inventors: Jung Pill Kim, Cary, NC (US); Jonghee Han, Cary, NC (US)

Correspondence Address: GERO G. MCCLELLAN;MOSER, PATTERSON & SHERIDAN, L.L.P., Suite 1500, 3040 Post Oak Blvd., Houston, TX, 77056, US

(73) Assignee: INFINEON TECHNOLOGIES NORTH AMERICA CORP.

(21) Appl. No.: 10/696,920

(22) Filed: Oct. 30, 2003

(51) Int. Cl. H03L 7/06

(52) U.S. Cl. 327/158

(57) ABSTRACT

Techniques and circuit configurations for fine phase adjustments, for example, in a delay-locked loop (DLL) circuit are provided. Multiple phase signals may be generated from a single current source by selectively coupling one or more delay elements to an output node of the current source. The delay elements may vary the timing of a signal generated by switching the current source.

### BACKGROUND OF THE INVENTION

1. Field of the Invention

The present invention generally relates to integrated circuit devices and, more particularly to delay locked loops utilized in integrated circuit devices.

2. Description of the Related Art

Delay locked loops (DLL) are utilized in a wide variety of integrated circuit (IC) devices to synchronize output signals with periodic input signals. In other words, the objective of the DLL is to adjust the phase difference between the input and output signals near zero. FIG. 1 illustrates an exemplary DLL circuit 100 configured to synchronize an output clock signal CK_{OUT} with an input clock signal CK_{IN}.

As illustrated, the DLL circuit 100 generally includes a delay line 102, phase detector 104, control logic 106 and a phase blender 108. The phase detector 104 compares the phase of CK_{OUT} to CK_{IN}, and generates a signal to the control logic 106, which adjusts the delay line 102 and phase blender 108, based on the detected phase difference. The control logic 106 may include any suitable circuitry, such as shift registers, or any other type registers, to control the delay line 102 and phase blender 108 to delay CK_{IN} sufficiently to synchronize CK_{OUT}. In other words, the control logic 106 may control the delay line 102 and phase blender 108, such that the delay between CK_{IN} and CK_{OUT} is substantially equal to a multiple of their clock period.

As illustrated in FIG. 2, the delay line 102 may include many delay blocks 110, each representing a single unit delay. Taps 112 may be provided between each delay block 110, allowing different delayed versions of CK_{IN} to be selected. For example, the signal V₁ on tap 112₁ corresponds to CK_{IN} delayed by one unit delay. Therefore, the total delay through the delay line 102 may be controlled by selecting the appropriate tap(s) 112 for output from the delay line 102. Typically, the unit delay is equal to the propagation delay of one or two inverters used in the delay block 110.

Unfortunately, this unit delay time may be too coarse (large) to provide the phase resolution required to adequately synchronize CK_{IN} and CK_{OUT} for high speed applications. Thus, the phase blender 108 may be configured to provide finer phase adjustments than the unit delays of the delay line 102 will allow. As illustrated, the phase blender 108 may take, as input, early and late phase delayed signals V_{E} and V_{L}, respectively, typically separated by one unit delay. For example, V_{E} and V_{L} may be obtained from adjacent taps 112ᵢ and 112ᵢ₊₁, respectively, of the delay line 102. The phase blender 108 then generates an output signal (e.g., CK_{OUT} in this case) that has a intermediate (or “blended”) phase between the phase of the signals V_{E} and V_{L}.

FIG. 3A illustrates an exemplary circuit configuration of a phase blender 108, configured to generate four signals separated in phase by approximately 90°. In other words, as illustrated in FIG. 3B, the signals are equally distributed by T/4, where T is the unit delay used in the delay line 102, which separates V_{E} and V_{L}. The desired signal may be selected for output via switches 150, for example, controlled by the control logic 106 shown in FIG. 1. As illustrated, signals V_{BL2}, V_{BL2}, and V_{BL3} may each be generated by blending V_{E} and V_{L} via a corresponding pair of blending inverters 130, with each pair including an inverter 130_{E} for receiving the early signal V_{E} and an inverter 130_{L} for receiving the late signal V_{L}. When the outputs of these blending inverters 130 reach the threshold level of comparators 140₁₋₃, the output signals V_{BL2}, V_{BL2}, and V_{BL3} are generated.

Generating a blended phase signal may be described with reference to the transistor representation of a pair of blending inverters 130 shown in FIG. 4A and the corresponding timing diagram of FIG. 4B. At T1, both V_{E} and V_{L} are low, and both PMOS transistors PE and PL of inverters 130_{E} and 130_{L} are switched on, while NMOS transistors NE and NL of inverters 130_{E} and 130_{L} are switched off. As a result, the (inverted) output V_{BLI} is initially a logic high.

At T2, the early signal V_{E} is asserted, switching PE off and NE on, while PL remains on. Thus, the voltage level of V_{BLI} is determined by the transistor on-resistances (current drive) of PL and NE. At T3, one unit delay after V_{E} is asserted, V_{L} is asserted, switching PL off and NL on, thus driving the V_{BLI} to the full logic low level. While not shown, similar switching occurs when V_{E} and V_{L} are de-asserted. For example, when V_{E} is de-asserted, PE is switched on and NE is switched off, while NL remains on, the voltage level of V_{BLI} is determined by the transistor on-resistances (current drive) of PE and NL. Finally, V_{L} is de-asserted, switching PL on and NL off, thus returning V_{BLI} to the full logic high level.

In general, the stronger the drive current for the early inverter 130_{E} relative to the late inverter 130_{L}, the smaller delay between V_{BLI} and V_{E}. Thus, the relative drive currents of each pair of blending inverters 130 may be varied (e.g., by varying the ratio of the device widths) to achieve the different phase signals. As an example, to generate V_{BL1} only T/4 latter than V_{E}, the device widths of the early inverter 130_{E} should be greater than the device widths of the late inverter 130_{L}. To generate V_{BL2} T/2 later than V_{E}, the device widths of the early and later inverters should be approximately the same. To generate V_{BL3} 3*T/4 from V_{E}, the device widths of the later inverter 130_{L} should be greater than the device widths of the early inverter 130_{E}.

While this type of blending circuit provides for fine phase adjustment of signals from the delay line 102, the circuit suffers from a number of disadvantages. For example, determining the sizes of blending inverters with adequate precision to generate phase signals having a desired resolution can be a difficult task. Moreover, as illustrated in FIG. 3A, each pair of phase blending inverters 130 has one or more current sources (e.g., PE and PL) and its own comparator 140. While the illustrated example has only four outputs, a real application may have several more outputs, or several cascaded stages. As a result, the large number of inverters and comparators may consume a significant amount of current.

Accordingly, there is a need for improved techniques and circuit configurations for the fine adjustment of a signal generate by a DLL circuit.

### SUMMARY OF THE INVENTION

Embodiments of the present invention generally provide improved techniques and circuit configurations for the fine adjustment of a signal generate by a DLL circuit.

One embodiment provides a phase blending circuit for generating a plurality of signals differing in phase relative to an early phase signal. The phase blending circuit generally includes a current source having a common output node, one or more delay elements, and one or more switches to selectively couple one or more of the delay elements to the common output node of the current source, wherein a time required for a voltage level at the common output node to fall below a threshold level after assertion of the early phase signal is dependent on which of the one or more delay elements are coupled to the common output node.

Another embodiment provides a phase blending circuit for generating a plurality of signals differing in phase relative to an early phase signal. The phase blending circuit generally includes a current source having a common output node and a control input for disabling the current source when a late phase signal trailing the early phase signal is asserted, a comparator having an input coupled with the common output node of the current source, a plurality of delay elements, a path for current flow from the common output node when the early phase signal is asserted, and a plurality of switches to selectively couple one or more of the delay elements to the output node of the current source for varying the time required for a voltage level of the common output node to fall below a threshold level as a result of current flow through the path.

Another embodiment provides a delay locked loop circuit for generating an output signal aligned with an input signal. The delay locked loop circuit generally includes a delay line for providing phase signals delayed relative to the input signal by one or more of unit delays, a phase blending circuit for generating a blended phase signal having a phase between early and late phase signals provided by the delay line, the phase blending circuit comprising a current source and one or more delay elements for selectively coupling to a common output node of the current source, wherein a time required for a voltage level at the common output node to fall below a threshold level after assertion of the early phase signal is dependent on which of the one or more delay elements are coupled to the common output node, and control logic configured to monitor skew between the input and output signals and, based on the skew, generate one or more control signals to select the early and late signals provided to the phase blending circuit and to selectively couple one or more of the delay elements to the common output node.

Another embodiment provides a dynamic random access memory (DRAM) device generally including a one or more memory elements and a delay locked loop circuit for synchronizing data output from the one or more memory elements with a clock signal. The delay locked loop circuit generally includes (i) a delay line, (ii) a phase blending circuit comprising a current source and one or more delay elements for selectively coupling to a common output node of the current source, wherein a time required for a voltage level at the common output node to fall below a threshold level after assertion of an early phase signal provided by the delay line is dependent on which of the one or more delay elements are coupled to the common output node, and (iii) control logic configured to monitor skew between the input and output signals and, based on the skew, generate one or more control signals to select the early signal provided to the phase blending circuit by the delay line and to selectively couple one or more of the delay elements to the common output node.

Another embodiment provides a method for generating a phase signal having a phase intermediate to phases of an early signal and a late signal. The method generally includes coupling the early signal to a control input of one or more switches to provide a path for current flow from a common output node of a current source through the one or more switches when the early signal is asserted and closing one or more switches to selectively couple one or more delay elements to the common output node of the current source, wherein a time required for a voltage level of the common output node to fall below a threshold level as a result of the current flow is dependent on which of the one or more switches are closed.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 illustrates an exemplary delay-locked loop (DLL) circuit.

FIG. 2 illustrates an exemplary delay line in accordance with the prior art.

FIGS. 3A-3B illustrate an exemplary DLL blender circuit and corresponding timing diagram, respectively, in accordance with the prior art.

FIGS. 4A-4B illustrate an exemplary schematic of an inverter pair of the DLL blender circuit if FIG. 3 and a corresponding timing diagram, respectively.

FIG. 5 illustrate an exemplary dynamic random access memory (DRAM) device utilizing a dynamic locked loop (DLL) circuit in accordance with an embodiment of the present invention.

FIG. 6 is a flow diagram of exemplary operations for synchronizing input and output signals utilizing the DLL circuit of FIG. 5.

FIGS. 7A-7B illustrate an exemplary DLL blender circuit in accordance with an embodiment of the present invention.

FIG. 7C illustrates an exemplary timing diagram corresponding to the DLL blender circuit of FIGS. 7A-7B.

FIG. 8 illustrates an exemplary DLL blender circuit in accordance with another embodiment of the present invention.

### DETAILED DESCRIPTION OF THE PREFERRED EMBODIMENTS

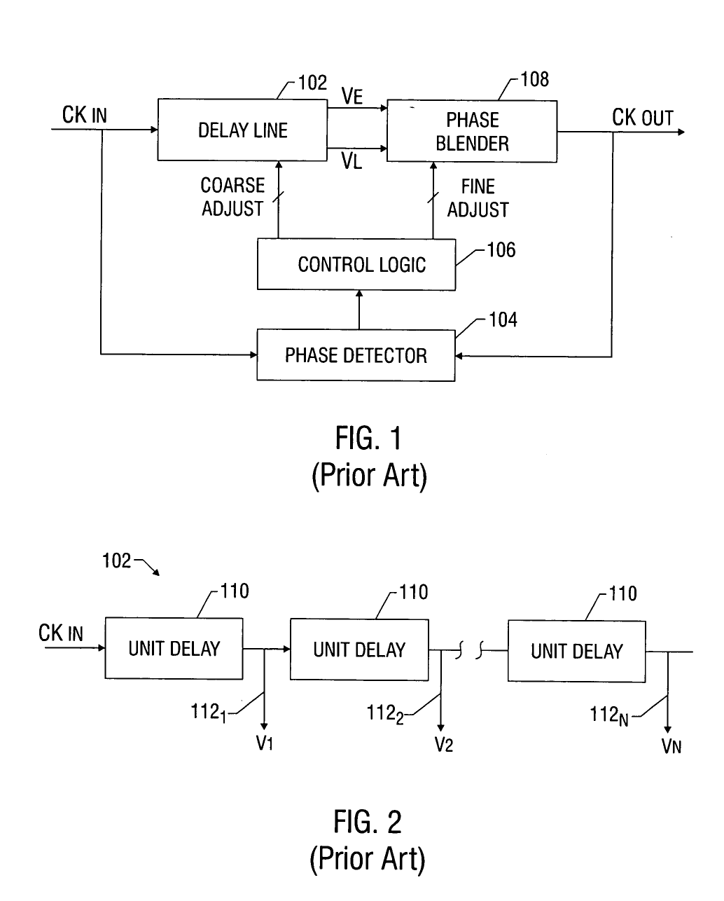

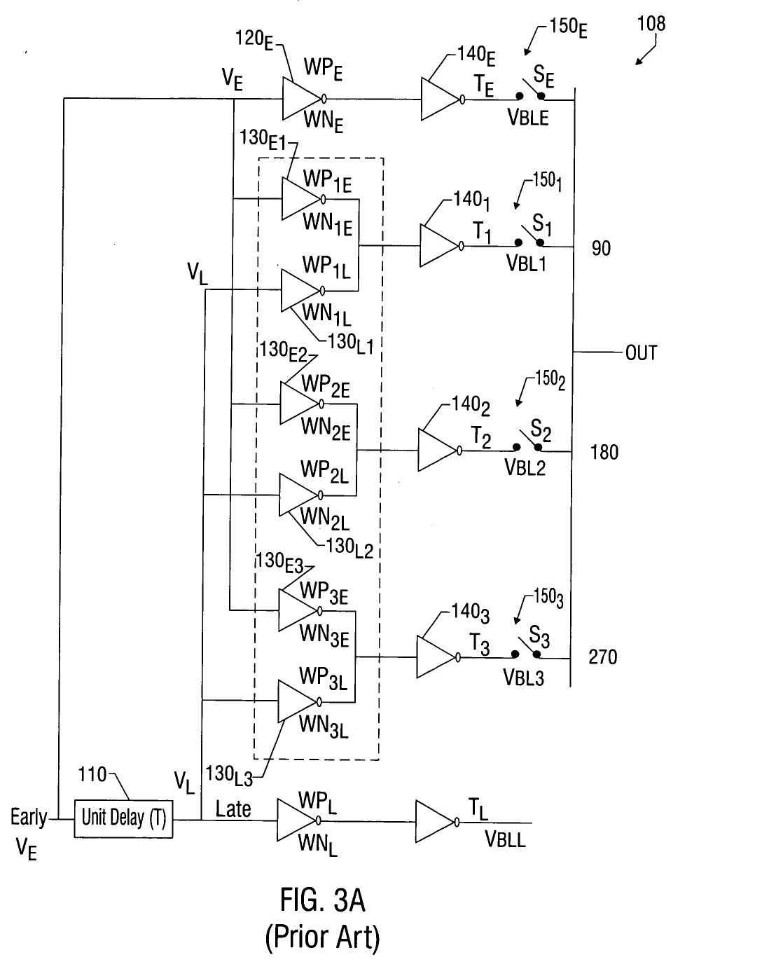

Embodiments of the present invention generally provide improved techniques and circuit configurations for fine phase adjustments, for example, in a delay-locked loop (DLL) circuit. Rather than utilize one or more different current sources to generate each fine adjust phase signal as in the prior art (e.g., the transistors PE and PL in each pair of blending inverters 130 of FIG. 1), embodiments of the present invention may generate multiple phase signals from a single current source. To generate signals with different phases, different delay elements that vary the timing of a signal generated by switching the current source may be selectively coupled to the current source. As a result, circuit configurations of the present invention may be simpler to design, simpler to manufacture, occupy less real estate, and consume less current.

As used herein, the term current source generally refers to any type of device used to supply the necessary current to generate a signal, such as a switching transistor (e.g., a PFET or NFET) coupled to a source power supply line (e.g., V_{DD}). The techniques and circuit configurations described herein may be utilized in a wide variety of applications to adjust the phase of a generated signal. However, to facilitate understanding, the following description will refer to embodiments utilizing the techniques and circuit configurations in a DLL circuit of a dynamic random access memory (DRAM) as a particular, but not limiting application example.

### An Exemplary Dram Device

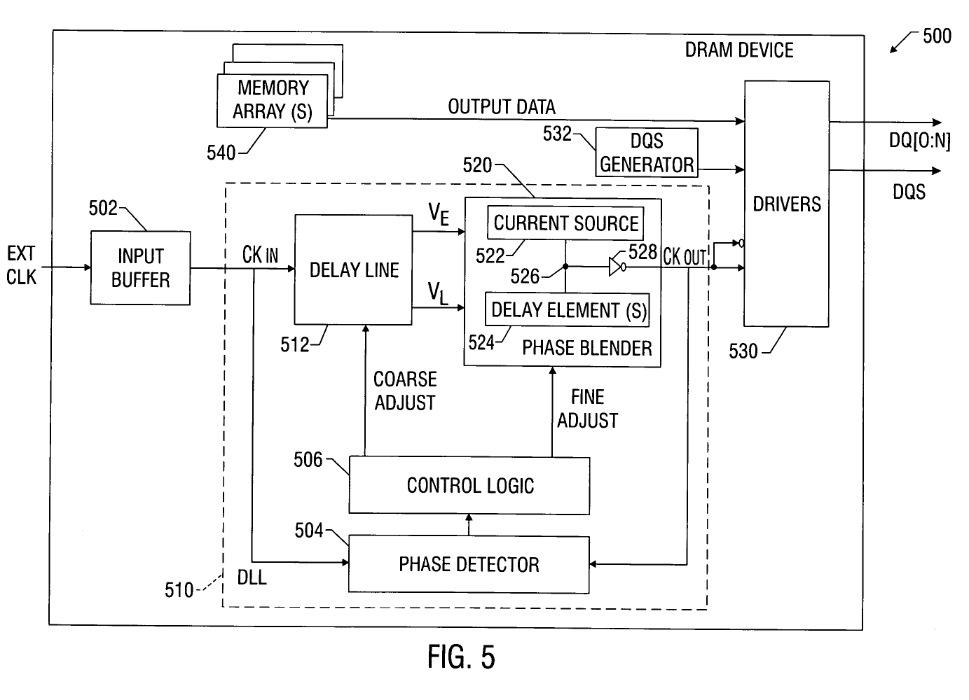

FIG. 5 illustrates an exemplary dynamic random access memory (DRAM) device 500 utilizing a dynamic locked loop (DLL) circuit 510 in accordance with an embodiment of the present invention. A typical requirement of DRAM specifications is that data from memory arrays 540 be available on output lines DQ[0:N] on the rising edge (and falling edge in double data rate devices) of an externally supplied clock signal (CLK). In some cases, the DRAM may supply a data strobe signal DQS, that should also be synchronized with CLK, indicating the data is available.

One approach to synchronize DQ or DQS with CLK would be to clock driver circuits 530 with CLK. However, a number of elements may contribute to a phase delay between CLK at the input of the device and CLK arriving at the driver circuit 530, such as an input buffer 502 and interconnection lines used to propagate CLK through the device 500. Variations in manufacturing processes, temperature, and operating clock frequencies may contribute to further delays. Thus, clocking the driver circuit 530 directly with CLK may be undesirable skew between CLK and DQ or DQS signals which may decrease the valid output data window.

However, the DLL circuit 510 may be used to synchronize the DQS and DQ signals with the CLK signal through the introduction of an artificial delay of CLK. Thus, the DLL circuit 510 may be used to increase the valid output data window by synchronizing the output of data with both the rising and falling edges of an output clock CK_{OUT} (in phase with CLK) used to clock the driver circuits 530. As illustrated, the DLL circuit 510 may include a delay line 512, phase detector 504, and control logic 506. As with conventional DLL circuits, the delay line 512 may include a chain of relatively coarse unit delays and may be used to make coarse phase adjustments, while the phase blender 520 may be used to make finer phase adjustments.

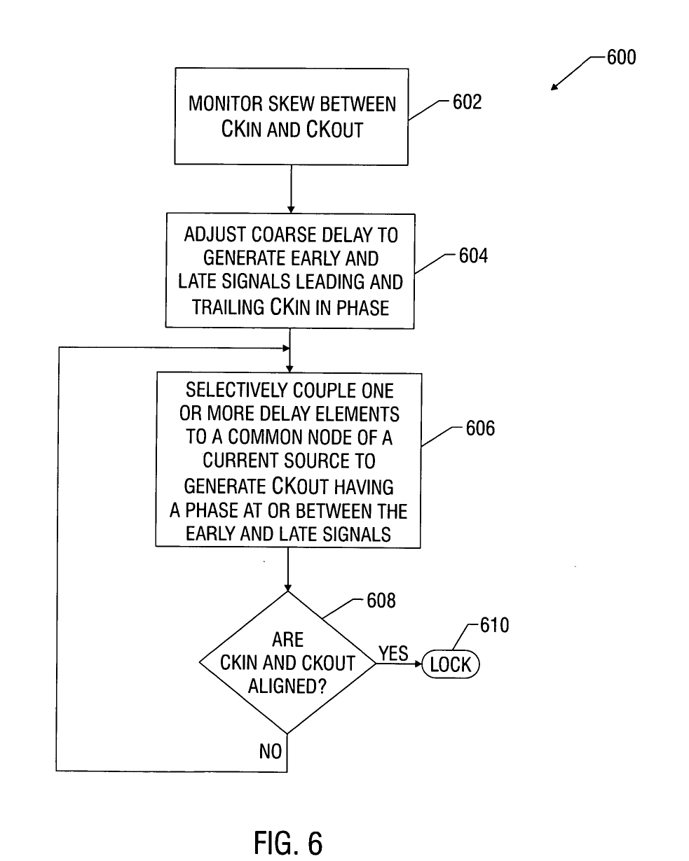

Operation of the DLL circuit 510 and phase blender 530 may be described with reference to FIG. 6, which illustrates a flow diagram of exemplary operations 600 for synchronizing input and output signals. For example, the operations 600 may be performed via the control logic 506 to control the delay line 512 and phase blender 530 during an initialization sequence of the DLL (e.g., power up or exiting a self-refresh mode). The operations 600 may also be performed continuously to make “run-time” adjustments to CK_{OUT}, for example, to compensate for changes in frequency to CLK or changes in delay thereof due to changing temperature.

In any case, the operations 600 begin at step 602, by monitoring skew (phase difference) between CK_{IN} and CK_{OUT}. For example, the control logic 506 may monitor one or more signals, generated by the phase detector 504, indicative of the phase difference between CK_{IN} and CK_{OUT}. At step 604, a coarse delay is adjusted to generate early and late signals leading and trailing CK_{IN} in phase. For example, the control logic 506 may generate one or more control signals to select adjacent taps of the delay line 512 to feed early and late signals V_{E} and V_{L} (e.g., differing in phase by one delay unit) to the phase blender 530.

At step 606, one or more delay elements are selectively coupled to a common node of a current source to generate CK_{OUT} having a phase at or between the early and late signals. For example, the phase blender 520 may include one or more delay elements 526, which may be selectively coupled to a common output node 526 of a current source 522. As will be described in greater detail below, the delay elements 524 may be used to vary the time required for a voltage level at the common node 526 to reach a threshold switching voltage level of a comparator 528 after the early signal V_{E} is asserted.

If CK_{IN} and CK_{OUT} are aligned, as determined at step 608 (e.g., based on feedback from the phase detector 504), the DLL is considered locked, at step 610. Otherwise, the operations 600 return to step 606 to vary the one or more delay elements 524 coupled to the common node 526 of the current source 520. The operations 606-608 may be repeated, until CK_{IN} and CK_{OUT} are aligned. For some embodiments, fine adjustments may be made by initially coupling the one or more delay elements 524 to the common node 526 that result in the smallest delay (e.g., CK_{OUT} in phase with the early signal V_{E}), and changing the coupled delay elements 524 in each pass to increase the delay until CK_{IN} and CK_{OUT} are aligned.

### Exemplary DLL Blender Circuits

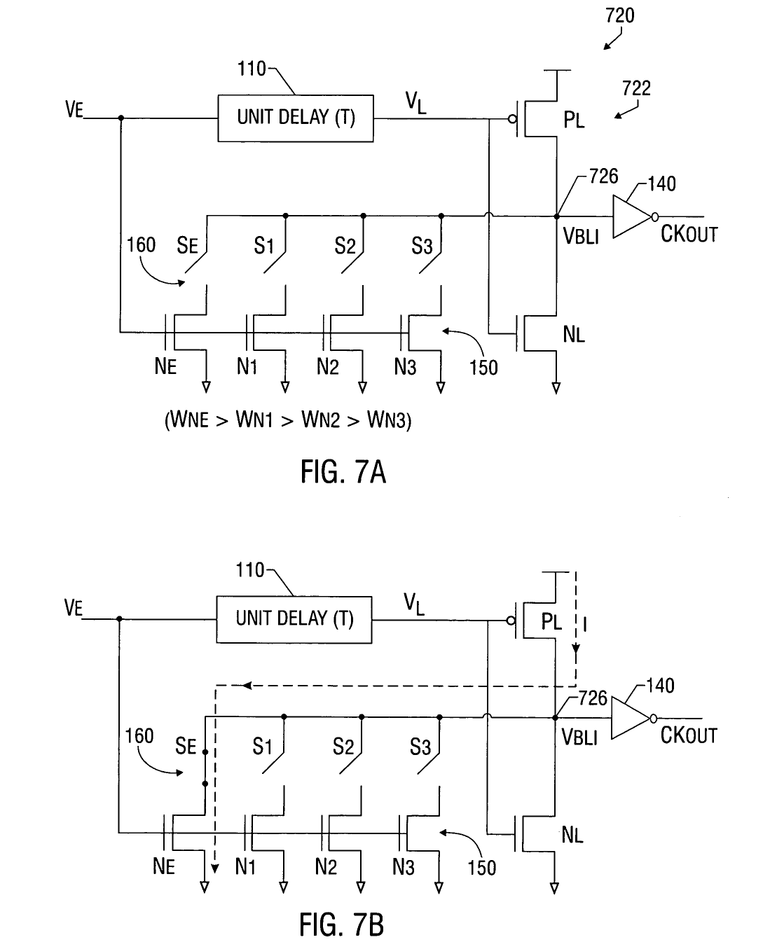

The delay elements 524 may comprise any suitable circuit components that affect the time between assertion of the early signal V_{E} and switching of the comparator 140. For example, as illustrated in FIG. 7A, a phase blender 720 may include one or more transistors 150 as delay elements. The transistors 150 may be coupled with a common node 726 of a current source 722 (a PMOS transistor PL) via one or more switches 160. For example, the one or more switches 160 may be opened or closed via signals generated by DLL control logic during fine phase adjustment (e.g., steps 606-608 of FIG. 6) of CK_{OUT}. The transistors 150 may vary the switching time of the comparator 140 by varying the effective resistance of the current path from the common node 726 when the early signal V_{E} is asserted.

For example, FIG. 7B illustrates the phase blender 720 with the switch SE closed to provide a current path through transistor NE when the early phase signal V_{E} is asserted. FIG. 7C illustrates an exemplary timing diagram for the early signal V_{E} (702), the late signal V_{L} (704), and the (inverted) blended signal VBLI 706 when the switch SE is closed. As illustrated, at time T1, with both VE and VL de-asserted, there is no current path to ground and the common node 726 is precharged to VDD. When the early signal V_{E} is asserted (line 702) at time T2, NE provides a current path from the common node 726 to ground. Thus, prior to assertion of the late signal V_{L} at time T3, the voltage level of V_{BLI} is a function of the effective turn-on resistances of PL and NE. Once the late signal is asserted, PL is turned off and NL is turned on, and the common node 726 is discharged through both NE and NL.

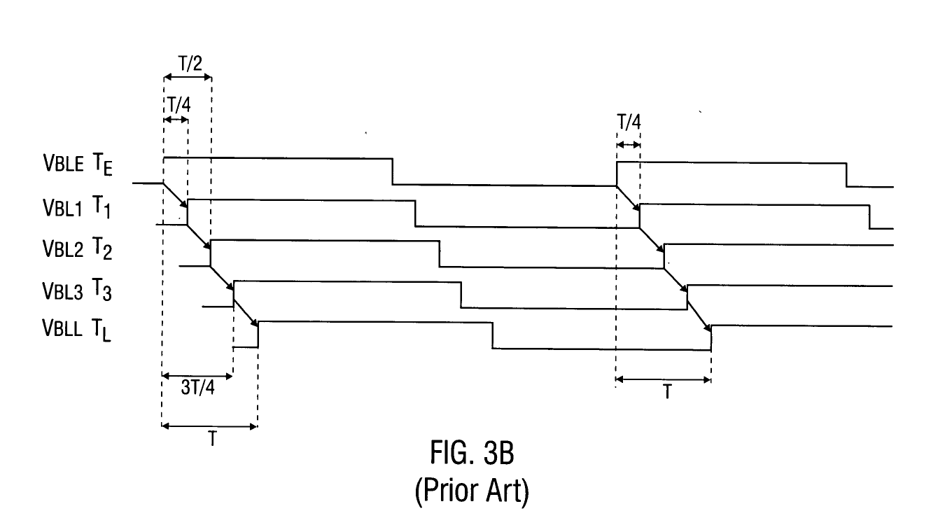

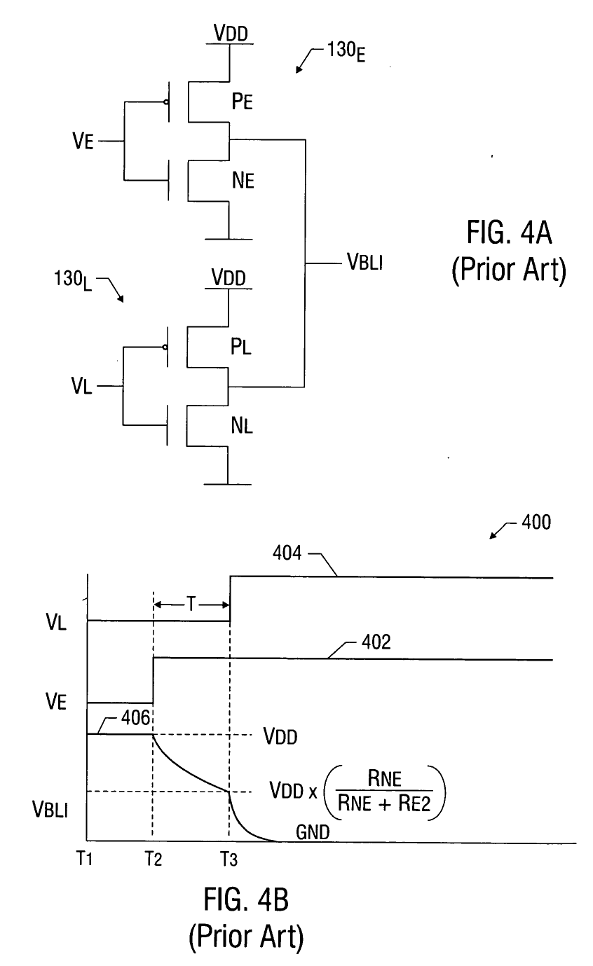

Thus, the dimensions of PL, NL, and NE (as well as the output capacitance at the common node 726) will determine the time at which V_{BLI} crosses the switching threshold voltage of the comparator 140. Accordingly, the dimensions of PL, NL, and NE may be chosen in an effort to ensure CK_{OUT} is phase aligned with the early signal V_{E}, when switch SE is closed. For some embodiments, the dimensions of the transistors 150 may be chosen to vary the effective resistance of each transistor in an effort to generate CK_{OUT} having evenly distributed phases (e.g., every 90° corresponding to blended voltage signals shown in FIG. 3B).

In other words, the dimensions of N1-N3 may be chosen in an effort to ensure CK_{OUT} is phase delayed from the early signal V_{E} by 90°, 180°, and 270° when switches S1, S2, and S3 are closed, respectively. As illustrated, because effective transistor resistance is generally inversely proportional to channel width, the widths of the transistors may decrease from NE to N3 (e.g., NE=2×N1=4×N2=8×N3). Of course, for some embodiments, multiple transistors 150 may be coupled to the common node concurrently to achieve the desired timing for any given phase delay. In other words, the dimensions of the transistors may be chosen such that the effective resistance of the transistors in parallel results in the desired switching time of the comparator 140.

By comparison, the circuit configuration of the DLL blender 720 has fewer components and is much simpler than the circuit configuration of the DLL blender 120 of FIG. 3A. As a result, it may be possible to provide finer adjustments (e.g., more than four blended phase signals) within the same or less circuit area. The additional blended phase signals may be provided by adding additional transistors 150 or by cascading multiple stages of blender circuits 720, for example, with each successive stage providing finer phase resolution. Further, by utilizing a single current source 722 and a single comparator 140, the DLL blender 720 may consume considerably less current than the conventional DLL blender 120.

As previously described, the switching time of the common node 726 of the current source 722 may also be determined by its output capacitance, which will generally include the input capacitance of the comparator 140 and any other capacitance on the common node 726. Thus, it may also be possible to vary the phase of CK_{OUT} by varying the capacitance of the common node 726.

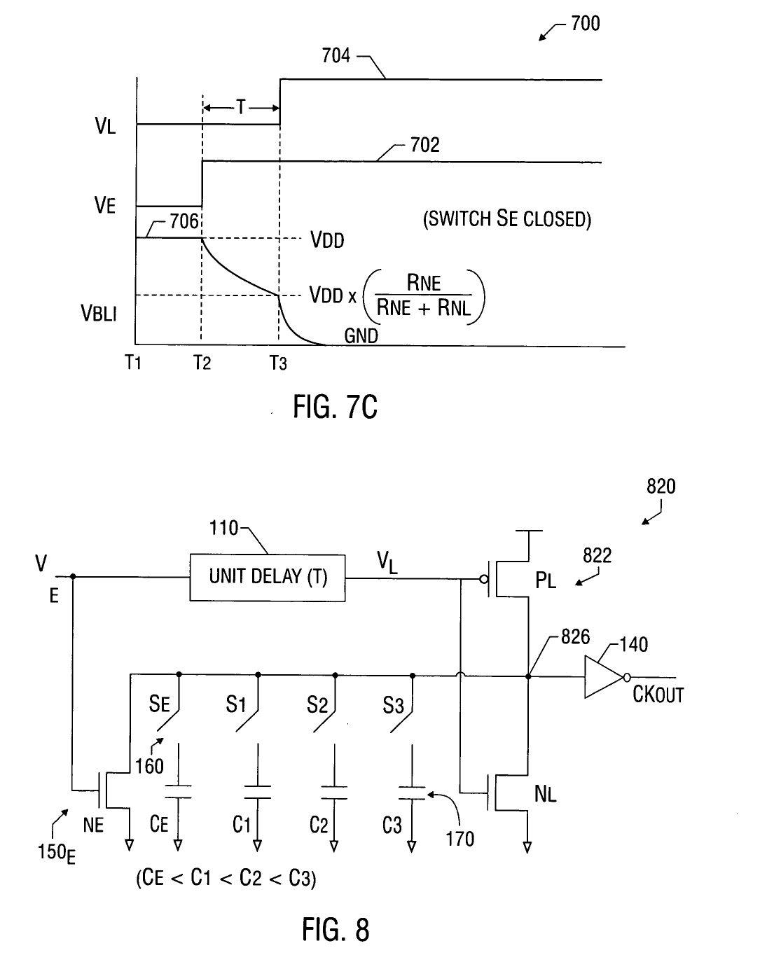

FIG. 8 illustrates an exemplary DLL blender circuit 820 in which the capacitance at a common node 826 of a current source 822 is varied by selectively coupling one or more capacitors 170 thereto. In other words, the one or more capacitors 170 may be selectively coupled to vary the discharge rate of the common node 826 through NE when the early signal V_{E} is asserted, and through NE and NL when the late signal V_{L} is later asserted.

Thus, the size of the capacitors 170 (CE and C1-C3) may be chosen in an effort to ensure the time at which V_{BLI} crosses the switching threshold of the comparator 140 corresponds to the desired phase signals (e.g., V_{BLE} and V_{BL1}-V_{BL3} of FIG. 3B). As illustrated, to generate the earliest blended signal V_{BLE} (e.g., in phase with the early signal V_{E}), when switch SE is closed, CE may be the smallest capacitor 170. Similarly, the sizes of C1-C3 may be increased incrementally in an effort to ensure CK_{OUT} is phase delayed from the early signal V_{E} by 90°, 180°, and 270° when switches S1, S2, and S3 are closed, respectively. Of course, for some embodiments, multiple capacitors 170 may be coupled to the common node concurrently to achieve the desired timing for any given phase delay. In other words, the values of the capacitors 170 may be chosen such that the effective parallel capacitance (which is additive) results in the desired switching time of the comparator 140.

The capacitors 170 may be any suitable type of capacitors and the exact type may depend on the type used elsewhere on a device utilizing the blending circuit 820. For example, if the device is a DRAM device, the capacitors may be fabricated using the same type of process as capacitors of the memory cells (e.g., deep trench or stacked capacitors), which may reduce overall system cost. Further, for some embodiments, the delay elements of a phase blending circuit may include a combination of capacitors and transistors, which may be coupled to a common current source, in any suitable combination, to generate a plurality of phase blended signals as described herein.

### CONCLUSION

By selectively coupling one or more delay elements to a common node of a blending circuit, embodiments of the present invention may allow multiple blended signals differing in phase from one or more reference signals to be generated using a single current source. Thus, a phase blending circuit in accordance with embodiments of the present invention may be simpler to design and implement than conventional blending circuits utilizing one or more separate current source for each blended signal, and may also occupy less circuit area and consume less current.

While the foregoing is directed to embodiments of the present invention, other and further embodiments of the invention may be devised without departing from the basic scope thereof, and the scope thereof is determined by the claims that follow.

1. A phase blending circuit for generating a plurality of signals differing in phase relative to an early phase signal, comprising:
a current source having a common output node;
one or more delay elements; and
one or more switches to selectively couple one or more of the delay elements to the common output node of the current source, wherein a time required for a voltage level at the common output node to fall below a threshold level after assertion of the early phase signal is dependent on which of the one or more delay elements are coupled to the common output node, wherein the one or more delay elements comprises a plurality of transistors having different physical dimensions to provide a path for current flow from the common output node of the current source in response to assertion of the early phase signal.

2. (canceled)

3. (canceled)

4. The phase blending circuit of claim 1, wherein the physical dimensions of the transistors are selected such that the phases of the plurality of signals are separated by a substantially equal phase.

5. The phase blending circuit of claim 1, wherein the one or more delay elements comprises at least one capacitor coupled with the common output node of the current source.

6. The phase blending circuit of claim 5, wherein the at least one capacitor comprises a plurality of capacitors having different values of capacitance.

7. The phase blending circuit of claim 6, wherein the capacitor values are selected such that the phases of the plurality of signals are separated by a substantially equal phase.

8. A phase blending circuit for generating a plurality of signals differing in phase relative to an early phase signal, comprising:
a current source having a common output node and a control input for disabling the current source when a late phase signal trailing the early phase signal is asserted;
a comparator having an input coupled with the common output node of the current source;
a plurality of delay elements;
a path for current flow from the common output node when the early phase signal is asserted; and
a plurality of switches to selectively couple one or more of the delay elements to the output node of the current source for varying the time required for a voltage level of the common output node to fall below a threshold level as a result of current flow through the path,
wherein the path includes a branch for the flow of current from the output node only when the late phase signal is asserted and the current source is disabled regardless of a state of the switches.

9. The phase blending circuit of claim 8, wherein the path for current flow comprises at least one transistor receiving the early phase signal as an input.

10. The phase blending circuit of claim 9, wherein the at least one transistor is one of the delay elements coupled to the common output node of the current source via one of the switches.

11. The phase blending circuit of claim 9, wherein the at least one transistor comprises an NMOS transistor and the current source comprises a PMOS transistor.

12. The phase blending circuit of claim 9, wherein the branch comprises at least one transistor receiving the late phase signal as an input, wherein the at least one transistor is of a different process type than a transistor used in the current source.

13. The phase blending circuit of claim 8, wherein the one or more delay elements are configured to allow generation of a plurality of signals having phases separated by a substantially equal phase.

14. A delay locked loop circuit for generating an output signal aligned with an input signal, comprising:
a delay line for providing phase signals delayed relative to the input signal by one or more of unit delays;
a phase blending circuit for generating a blended phase signal having a phase between early and late phase signals provided by the delay line, the phase blending circuit comprising a current source and one or more delay elements for selectively coupling to a common output node of the current source, wherein a time required for a voltage level at the common output node to fall below a threshold level after assertion of the early phase signal is dependent on which of the one or more delay elements are coupled to the common output node; and
control logic configured to:
(a) determine if the input and output signals are aligned within an accepted tolerance;
(b) if not, modify one or more control signals to couple a different one or more of the delay elements to the common output node; and
(c) repeat steps (a)-(b) until the input and output signals are aligned within the accepted tolerance

15. (canceled)

16. The delay locked loop circuit of claim 14, wherein:
the phase blending circuit further comprises a comparator having an input node coupled with the common output node of the current source; and
the threshold level is the threshold level of the comparator.

17. The delay locked loop circuit of claim 16, wherein the output signal is generated on an output node of the comparator.

18. A dynamic random access memory (DRAM) device, comprising:
one or more memory elements; and
a delay locked loop circuit for synchronizing data output from the one or more memory elements with a clock signal comprising (i) a delay line, (ii) a phase blending circuit comprising a current source and a plurality of delay transistors having different physical dimensions for selectively coupling to a common output node of the current source, wherein a time required for a voltage level at the common output node to fall below a threshold level after assertion of an early phase signal provided by the delay line is dependent on which of the delay transistors are coupled to the common output node, and (iii) control logic configured to monitor skew between the input and output signals and, based on the skew, generate one or more control signals to select the early signal provided to the phase blending circuit by the delay line and to selectively couple one or more of the delay transistors to the common output node.

19. (canceled)

20. The DRAM device of claim 18, further comprising a plurality of capacitors for selectively coupling to the common output node of the current source.

21. The DRAM device of claim 20, wherein the plurality of capacitors are of the same type as capacitors utilized in the memory elements.

22. A method for generating a phase signal having a phase intermediate to phases of an early signal and a late signal, comprising:
coupling the early signal to a control input of one or more switches to provide a path for current flow from a common output node of a current source through the one or more switches when the early signal is asserted; and
closing one or more switches to selectively couple one or more of a plurality of delay transistors having different physical dimensions to the common output node of the current source, wherein a time required for a voltage level of the common output node to fall below a threshold level as a result of the current flow is dependent on which of the one or more switches are closed.

23. The method of claim 22, further comprising coupling the late signal to a control input of the current source to disable the current source when the late signal is asserted.

24. (canceled)

25. (canceled)

26. The method of claim 22, further comprising closing one or more switches to selectively couple one or more of a plurality of capacitors to the common output node of the current source.

27. The method of claim 22, wherein:
the late signal trails the early signal by a unit delay; and
the switches and delay transistors are configured to provide the delayed signal differing in phase from the early signal by a fraction of the unit delay, wherein the fraction depends on which of the switches are closed.
